(19) United States
(12) Patent Application Publication
(10) Pub. No.: US 2025/0096656 A1
(43) Pub. Date: Mar. 20, 2025

(54) POWER CONVERSION APPARATUS

(71) Applicant: FUJI ELECTRIC CO., LTD., Kawasaki-shi (JP)

(72) Inventor: Takanori SHINTANI, Suzuka-shi (JP)

(21) Appl. No.: 18/786,578

(22) Filed: Jul. 29, 2024

(30) Foreign Application Priority Data
Sep. 20, 2023 (JP) 2023-152324

(51) Int. Cl. H02K 11/33; H02M 3/00; H02M 7/00

(52) U.S. Cl. CPC H02K 11/33; H02M 3/003; H02M 7/003

(57) ABSTRACT

A power conversion apparatus is arranged on or above a load for supplying electric power to the load and includes an inverter for converting direct current power input from a direct current power supply into alternate current power and supplying the alternate current power to the load, and a DCDC converter for converting a voltage of the direct current power into a different voltage. The inverter and the DCDC converter are stacked or layered in this order from the load side.

### CROSS-REFERENCE TO RELATED APPLICATION

The present application is based on, and claims priority from, a Japanese Patent Application No. JP2023-152324 filed on Sep. 20, 2023, the disclosure of which is hereby incorporated by reference herein in its entirety.

### BACKGROUND

### Technical Field

The present disclosure relates to a power conversion apparatus, and particularly to a power conversion apparatus including a direct current/direct current or a DC-DC converter.

### Description of the Background Art

Power conversion apparatuses including a direct current/direct current or a DC-DC converter are known in the art. Such a power conversion apparatus is disclosed in International Publication No. WO 2015/163143 (Patent Document 1), for example.

International Publication No. WO 2015/163143 discloses a power conversion apparatus including an inverter device, a DC-DC converter (direct current/direct current converter), and a housing accommodating the inverter device and the DC-DC converter. The inverter device includes the semiconductor modules constructs upper and the lower arms, and the like. The DC-DC converter includes MOSFETs, a high voltage circuit board on which MOSFETs are mounted, and the like. In the above Patent Document 1, the DC-DC converter and the inverter device are stacked in this order from a lower side in the housing.

### SUMMARY

Here, in power conversion apparatuses as described in International Publication No. WO 2015/163143, the DC-DC converter is a component that is replaced with a new component on a regular basis. In a case in which the power conversion apparatus in International Publication No. WO 2015/163143 is arranged on or above a load, the DC-DC converter is interposed between the load and the inverter device. For this reason, the DC-DC converter (direct current/direct current converter) is not easily replaced with a new one.

One or more embodiments of the present invention is intended to solve the above problem, and one object of one or more embodiments of the present invention is to provide a power conversion apparatus capable of allowing easy replacement if a direct current/direct current converter even in a case in which the power conversion apparatus is arranged on or above a load.

In order to attain the aforementioned object, a power conversion apparatus configured to be arranged on or above a load for supplying electric power to the load according to one aspect of the present invention includes an inverter for converting direct current power input from a direct current power supply into alternate current power and supplying the alternate current power to the load; and a direct current/direct current converter for converting a voltage of the direct current power into a different voltage, wherein the inverter and the direct current/direct current converter are layered in this order from the load side.

In the power conversion apparatus according to the aforementioned one aspect, as discussed above, the inverter and the direct current/direct current converter are layered in this order from the load side. According to this configuration, even in a case in which the power conversion apparatus is arranged on or above the load, because the direct current/direct current converter is arranged on a side opposite to the load, it is possible to easily replace the direct current/direct current converter.

In the power conversion apparatus according to the aforementioned aspect, in one or more arrangements, a housing accommodating the inverter and the direct current/direct current converter is further provided; that the housing has an opening on a side opposite the load; and that the direct current/direct current converter is exposed through the opening of the housing. According to this configuration, even in a case in which the inverter and the direct current/direct current converter are accommodated in the housing, because the direct current/direct current converter is exposed through the opening of the housing, it is possible to easily replace the direct current/direct current converter.

In this configuration, in one or more arrangements, the housing is fixed to the load by a fastener. According to this configuration, even in a case in which the housing is fixed to the load by the fastener, because the direct current/direct current converter is exposed through the opening of the housing, it is possible to easily replace the direct current/direct current converter.

In the power conversion apparatus according to the aforementioned aspect, in one or more arrangements, the load includes an electric motor for an electric car. According to this configuration, even in a case in which the power conversion apparatus is arranged on or above the electric motor for the electric car, it is possible to easily replace the direct current/direct current converter.

In the power conversion apparatus according to the aforementioned aspect, in one or more arrangements, a base on or above which the inverter and the direct current/direct current converter are arranged is further provided; and that the direct current/direct current converter is arranged on a side of the base opposite to the load. According to this configuration, even in a case in which the direct current/direct current converter is arranged on the base, because the direct current/direct current converter is arranged on the side of the base opposite to the load, it is possible to easily replace the direct current/direct current converter.

In this configuration, in one or more arrangements, the direct current/direct current converter is fixed to the base by a fastener. According to this configuration, the direct current/direct current converter can be easily replaced simply by releasing a fastened state of the fastener.

In the power conversion apparatus according to the aforementioned aspect, in one or more arrangements, a base on or above which the inverter and the direct current/direct current converter are arranged, and a boost converter arranged on an input side of the inverter to boost the direct current power input from the direct current power supply and to supply the direct current power boosted to the inverter are further provided; and that the boost converter is arranged on a side of the base opposite to the load. According to this configuration, even in a case in which the power conversion apparatus is arranged on or above the load, because the boost converter is arranged on the side opposite to the load, it is possible to easily replace the boost converter.

In this configuration, in one or more arrangements, the boost converter is fixed to the base by a fastener. According to this configuration, the boost converter can be easily replaced simply by releasing a fastened state of the fastener.

The foregoing and other objects, features, aspects and advantages accompanying one or more embodiments of the present invention will become more apparent from the following detailed description when taken in conjunction with the accompanying drawings.

### BRIEF DESCRIPTION OF THE DRAWINGS

FIG. 1 is a perspective view showing a power conversion apparatus according to one embodiment arranged on a load.

FIG. 2 is a plan view showing a circuit diagram of a power conversion apparatus according to the one embodiment.

FIG. 3 is a perspective view showing the power conversion apparatus (without a housing) according to the one embodiment.

FIG. 4 is an exploded perspective view of the power conversion apparatus (without the housing) according to the one embodiment as viewed from an upward side.

FIG. 5 is a perspective view showing a base of the power conversion apparatus according to the one embodiment as viewed from a downward side.

FIG. 6 is a side view of the power conversion apparatus (without the housing) according to the one embodiment.

### DESCRIPTION OF THE EMBODIMENTS

Embodiments embodying the present invention will be described with reference to the drawings.

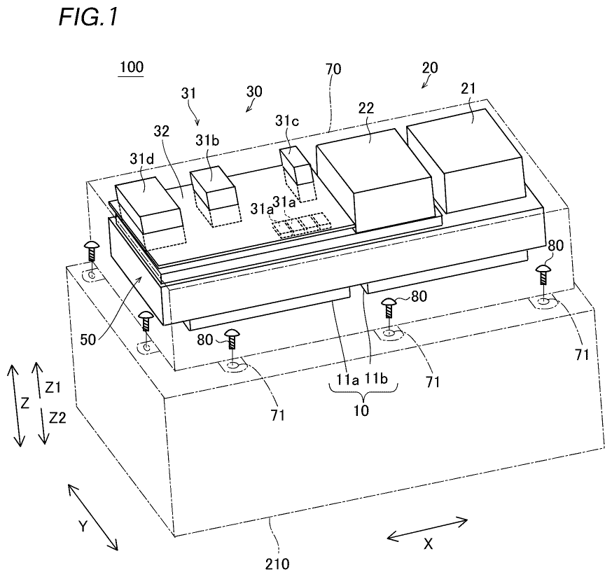

A configuration of a power conversion apparatus 100 according to one embodiment of the present invention will be described with reference to FIGS. 1 to 6. As shown in FIG. 1, the power conversion apparatus 100 is arranged on a load 210. The load 210 includes an electric motor for an electric car. In this case, the power conversion apparatus 100 is installed on a vehicle.

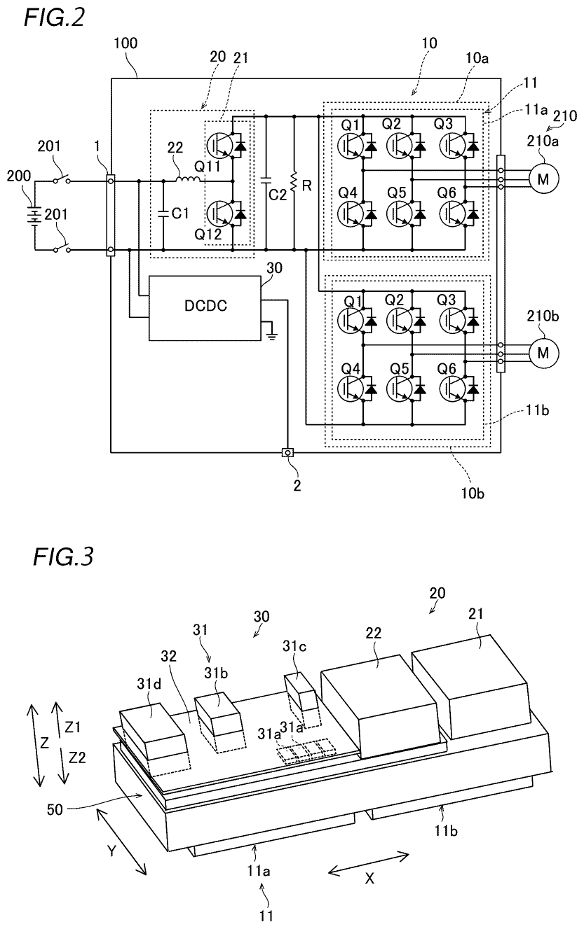

A circuit configuration of the power conversion apparatus 100 is described with reference to FIG. 2. The power conversion apparatus 100 includes an inverter 10. The inverter 10 converts direct current power input from the direct current power supply 200 into alternate current power, and supplies the alternate current power to the load 210. Switches 201 are connected between the power conversion apparatus 100 and the direct current power supply 200.

The inverter 10 includes switching element modules 11. The switching element modules 11 convert direct current power into alternating current power. Each switching element module 11 includes semiconductor switching elements Q1, Q2 and Q3 that construct an upper arm, and semiconductor switching elements Q4, Q5 and Q6 that construct a lower arm.

The inverter 10 includes a first inverter 10a and a second inverter 10b. Switching element modules 11 include a first switching element module 11a included in the first inverter 10a, and a second switching element module 11b included in the second inverter 10b. Also, the load 210 includes a first load 210a and a second load 210b. The first inverter 10a converts the direct current power input from the direct current power supply 200 into alternate current power, and supplies the alternate current power to the first load 210a. The second inverter 10b converts the direct current power input from the direct current power supply 200 into alternate current power, and supplies the alternate current power to the second load 210b.

The power conversion apparatus 100 includes a boost converter 20. The boost converter 20 is arranged on the input side of the inverter 10. The boost converter 20 increases a voltage of the direct current power input from the direct current power supply 200, and to supply the direct current power whose voltage is increased to the inverter 10. The boost converter 20 includes a boost switching element module 21, and a reactor 22. The boost switching element module 21 includes boost switching elements Q11 and Q12. The boost switching elements Q11 and Q12 construct the upper and lower arms, respectively. In addition, the boost converter 20 includes a capacitor C1. The reactor 22 is connected between a positive side of the direct current power supply 200, and a connection point between the boost switching element Q11 and the boost switching element Q12. Also, the capacitor C1 is connected in parallel to the boost switching element Q12.

In addition, the power conversion apparatus 100 includes a capacitor C2 and a resistor R. The capacitor C2 and the resistor R are connected between the boost converter 20 and the inverter 10. The capacitor C2 and the resistor R are connected in parallel to each other.

The power conversion apparatus 100 includes a DCDC converter 30. The DCDC converter 30 converts a voltage of the direct current power into a different voltage. Specifically, the DCDC converter 30 reduces the voltage of the direct current power input from the direct current power supply 200 through a connector 1. Also, the DCDC converter 30 supplies the voltage reduced to an output terminal 2. The DCDC converter 30 is an example of the “direct current/direct current converter” recited in the claims of the present application.

A structure of the power conversion apparatus 100 is now described. As shown in FIG. 1, the power conversion apparatus 100 includes a base 50 and a housing 70 in addition to the inverter 10, the boost converter 20 and the DCDC converter 30. In this embodiment, the inverter 10, the base 50, and the DCDC converter 30 are stacked or layered in this order from the load 210 side. The following description describes configurations of them.

As shown in FIG. 3, the DCDC converter 30 includes direct current/direct current converter element 31, and a direct current/direct current converter board 32 on which the direct current/direct current converter element 31 is mounted. The direct current/direct current converter board 32 has a flat plate shape. The direct current/direct current converter element 31 mounted on the direct current/direct current converter board 32 includes converter switching elements 31a, a transformer 31b, a resonant reactor 31c, and a smoothing reactor 31d. The converter switching elements 31a are installed on a part on the back side (Z2 side) with respect to the direct current/direct current converter board 32. The transformer 31b, the resonant reactor 31c and the smoothing reactor 31d are arranged to pass through the direct current/direct current converter board 32.

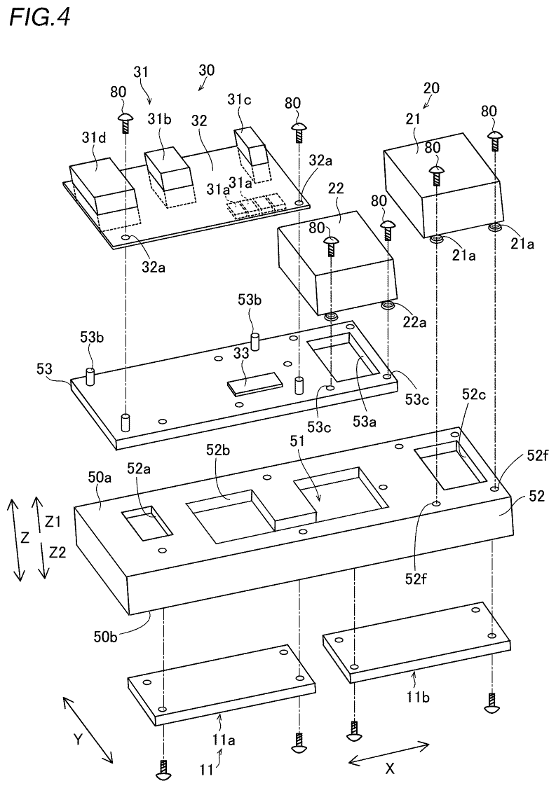

As shown in FIG. 2, each switching element module 11 includes the semiconductor switching elements Q1 to Q6. The semiconductor switching elements Q1 to Q6 are covered by a housing of a resin or the like. As shown in FIG. 4, each switching element module 11 has a rectangular box shape as viewed in a direction orthogonal to a surface of the switching element module 11.

As shown in FIG. 4, the power conversion apparatus 100 includes the base 50. The base 50 has a flat plate-like shape. The inverter 10 and the DCDC converter 30 are arranged on the base 50. Also, the base 50 is formed of a metal having a relatively high thermal conductivity, such as aluminum, for example. The base 50 has a rectangular shape as viewed in a direction orthogonal to a front surface 50a (a surface on the Z1 side) and a back surface 50b (a surface on the Z2 side) of the base 50.

As shown in FIG. 4, the base 50 includes a cooling flow path 51. Also, as shown in FIG. 6, the cooling flow path 51 includes flow paths arranged on the Z1 side in the base 50, flow paths arranged on the Z2 side in the base 50, and flow paths connected between the flow paths arranged on the Z1 side and the flow paths arranged on the Z2 side.

Here, in this embodiment, as shown in FIG. 4, the DCDC converter 30 is arranged on a side of the base 50 opposite to the load 210. Specifically, the DCDC converter 30 is arranged on the front surface 50a of the base 50 on the Z1 side. The DCDC converter 30 is fixed to the base 50 by fasteners 80. Specifically, the DCDC converter 30 is attached to a lid 53 of the base 50 by the fasteners 80. The lid 53 includes bosses 53b protruding toward the Z1 side. The DCDC converter 30 is attached to the bosses 53b by the fasteners 80 passing through holes 32a provided in the direct current/direct current converter board 32 of the DCDC converter 30. For example, the bosses 53b are two or more bosses. Also, the direct current/direct current converter board 32 on which the direct current/direct current converter element 31 is mounted to the base 50 so as to extend along the front surface 50a of the flat-plate-like base 50.

The first switching element module 11a and the second switching element module 11b are attached to the base 50 so as to extend along the back surface 50b of the flat-plate-like base 50. Specifically, the first switching element module 11a and the second switching element module 11b are arranged adjacent to each other in a longitudinal direction (X direction) of the first switching element module 11a and the second switching element module 11b. According to this arrangement, because a width of the base 50 in Y-direction is short, the power conversion apparatus 100 is downsized compared with the conventional apparatus. Also, the first switching element module 11a and the second switching element module 11b are attached to the base 50 by the fasteners 80.

The boost converter 20 is attached to the base 50 so as to extend along the front surface 50a of the flat-plate-like base 50. Specifically, the boost converter 20 is attached onto the front surface 50a, which is the side of the base 50 opposite to the load 210. The boost converter 20 is arranged adjacent to the DCDC converter 30 so as to extend in the longitudinal direction (X direction) of the flat-plate-like base 50.

Specifically, the boost converter 20 includes the boost switching element module 21, and the reactor 22. The boost switching element module 21 and the reactor 22 are attached to the base 50 so as to extend along the front surface 50a of the flat-plate-like base 50. Also, the direct current/direct current converter board 32, the reactor 22, and the boost switching element module 21 are attached to the base 50 so as to extend along the front surface 50a of the flat-plate-like base 50 and to be arranged adjacent to each other. The direct current/direct current converter board 32, the reactor 22, and the boost switching element module 21 are attached in this order to the front surface 50a of the base 50.

In this embodiment, the reactor 22 and the boost switching element module 21 are fixed to the base 50 by the fasteners 80. Specifically, the reactor 22 is fixed to the lid 53 of the base 50 by the fasteners 80 passing through holes 22a of the reactor 22 into holes 53c of the lid. For example, the holes 22a have two or more holes. The boost switching element module 21 is fixed to a cooler main part 52 of the base 50 by the fasteners 80 passing through holes 21a of the boost switching element module 21 into holes 52f of the cooler main part. For example, the holes 21a are two or more holes.

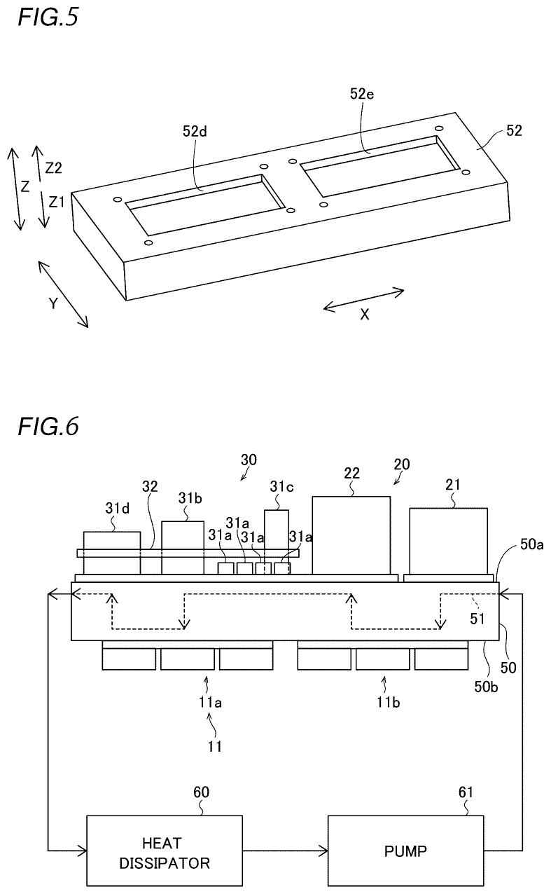

As shown in FIG. 4, the base 50 includes the cooler main part 52 formed of a metal for forming the cooling flow path 51, and the lid 53 formed of a metal for forming the cooling flow path 51 together with the cooler main part 52. The lid 53 has an opening 53a. Also, the cooler main part 52 has an opening 52a, an opening 52b and an opening 52c, which are opened on the Z1 side of the cooler main part. In addition, as shown in FIG. 5, the cooler main part 52 has an opening 52d and an opening 52e, which are opened on the Z2 side of the cooler main part. The opening 53a of the lid 53 is covered by the reactor 22. Specifically, the reactor 22 includes a reactor main part, and a lid formed of a metal for the reactor 22, and the opening 53a of the lid 53 is covered by the lid for the reactor 22. The opening 52a and the opening 52b are covered by the lid 53. The opening 52c is covered by the boost switching element module 21. Specifically, the boost switching element module 21 includes a boost-switching-element-module main part, and a lid formed of a metal for the boost switching element module 21, and the opening 52c is covered by the lid for the boost switching element module 21. The opening 52d and the opening 52e are covered by the first switching element module 11a and the second switching element module 11b, respectively. Specifically, the first switching element module 11a includes a main part of the switching element module 11a, and a lid formed of a metal for the first switching element module 11a, and the opening 52d is covered by the lid for the first switching element module 11a. The same goes for the opening 52e.

In this embodiment, as shown in FIG. 4, the direct current/direct current converter element 31 includes the converter switching elements 31a. The converter switching elements 31a are attached on a surface of the direct current/direct current converter board 32 on the lid 53 side (Z2 side surface) to the lid 53 through a thermally conductive part 33 to be in contact with the lid. That is, the lid 53, the thermally conductive part 33, and a set of the converter switching elements 31a are stacked or layered in this order. Heat that is generated by the converter switching elements 31a is dissipated to the lid 53 through the thermally conductive part 33. The thermally conductive part 33 is a ceramics sheet, for example.

Also, as shown in FIG. 6, the cooling liquid that flows out of the cooling flow path 51 is cooled by dissipating its heat by using a heat dissipator 60. Also, the cooling liquid that is cooled by the heat dissipator 60 is fed by a pump 61, and flows back into the cooling flow path 51. The heat dissipator 60 includes a heat exchanger to be cooled by outside air. The heat dissipator 60 is a radiator, for example. Alternatively, in one arrangement, the pump 61 is connected between the outlet of the cooling flow path 51 and the heat dissipator 60 so that the cooling liquid before the heat dissipation by the heat dissipator 60 is fed by the pump 61. For example, the cooling liquid is water, antifreeze, or the like.

As shown in FIG. 6, the inverter 10 is arranged on the back surface 50b of the base 50, and is cooled by the cooling liquid that flows on the Z2 side of the base 50. Specifically, the first switching element module 11a and the second switching element module 11b are arranged on the back surface 50b of the base 50, and cooled by the cooling liquid that flows on the Z2 side of the base 50.

Also, the DCDC converter 30 is arranged on the front surface 50a of the base 50, and is cooled by the cooling liquid that flows on the Z1 side of the base 50. Specifically, the converter switching elements 31a, the transformer 31b, the resonant reactor 31c, the smoothing reactor 31d, the boost switching element module 21, and the reactor 22 are arranged on the front surface 50a of the base 50, and are cooled by the cooling liquid that flows on the Z1 side of the base 50.

Parts in the DCDC converter 30 are arranged taking into account influence of thermal interference with the reactor 22. Specifically, in arrangement of parts that are the converter switching element 31a, the transformer 31b, the resonant reactor 31c, and the smoothing reactor 31d, parts that have low heat resistance are prevented from being arranged close to the reactor.

The DCDC converter 30 includes parts such as a fuse, a capacitor, and a Hall sensor element in addition to the direct current/direct current converter element 31, and these parts dissipate heat through heat dissipating members to the front surface 50a of the base 50.

At least a part of the DCDC converter 30 on the reactor 22 side can be covered by a shielding cover to reduce thermal interference with the reactor 22.

Also, the cooling flow path 51 is formed to cool parts to which higher priority is assigned based on thermal resistance are arranged among the first switching element module 11a, the second switching element module 11b, the converter switching elements 31a, the transformer 31b, the resonant reactor 31c, the smoothing reactor 31d, the boost switching element module 21, and the reactor 22.

In this embodiment, as shown in FIG. 1, the housing 70 accommodates the inverter 10 and the DCDC converter 30. Specifically, the housing 70 accommodates the inverter 10, the boost converter 20, the base 50 and the DCDC converter 30, and the inverter 10, the base 50 and the DCDC converter 30 are stacked or layered in this order in the Z1 direction in the housing 70. Also, the housing 70 has an opening on the Z1 side, which is opposite to the load 210, and the DCDC converter 30 is exposed through the opening in the housing 70. The boost switching element module 21 and the reactor 22 of the boost converter 20 are also exposed through the opening of the housing 70. In addition, the housing 70 is fixed to the load 210 by the fasteners 80. Specifically, the housing 70 is fixed to the load 210 by the fasteners 80 passing through holes 71 arranged on an outer periphery of the housing 70.

### Advantages of the Embodiment

In this embodiment, the following advantages are obtained.

In this embodiment, as described above, the inverter 10 and the DCDC converter 30 are stacked or layered in this order from the load 210 side. Accordingly, even in a case in which the power conversion apparatus 100 is arranged on the load 210, because the DCDC converter 30 is arranged on the side opposite to the load 210, it is possible to easily replace the DCDC converter 30.

In this embodiment, as described above, the power conversion apparatus 100 further includes the housing 70 accommodating the inverter 10 and the DCDC converter 30. The housing 70 has an opening on the side opposite to the load 210, and the DCDC converter 30 is exposed through the opening in the housing 70. Accordingly, even in a case in which the inverter 10 and the DCDC converter 30 are accommodated in the housing 70, because the DCDC converter 30 is exposed through the opening of the housing 70, it is possible to easily replace the DCDC converter 30.

In this embodiment, as described above, the housing 70 is fixed to the load 210 by the fasteners 80. Accordingly, even in a case in which the housing 70 is fixed to the load 210 by the fasteners 80, because the DCDC converter 30 is exposed through the opening of the housing 70, it is possible to easily replace the DCDC converter 30.

In this embodiment, as described above, the load 210 includes an electric motor for an electric car. Accordingly, even in a case in which the power conversion apparatus 100 is arranged on or above the electric motor for the electric car, it is possible to easily replace the DCDC converter 30.

In this embodiment, as described above, the power conversion apparatus 100 further includes the base 50 on which the inverter 10 and the DCDC converter 30 are arranged. The DCDC converter 30 is arranged on the side of the base 50 opposite to the load 210. Accordingly, even in a case in which the DCDC converter 30 is arranged on the base 50, because the DCDC converter 30 is arranged on the side of the base 50 opposite to the load 210, it is possible to easily replace the DCDC converter 30.

In this embodiment, as described above, the DCDC converter 30 is fixed to the base 50 by the fasteners 80. Accordingly, the DCDC converter 30 can be easily replaced simply by releasing fastened states of the fasteners 80.

In this embodiment, as described above, the power conversion apparatus 100 further includes the base 50 on which the inverter 10 and the DCDC converter 30 are arranged, and the boost converter 20 arranged on an input side of the inverter 10 to boost the direct current power input from the direct current power supply 200 and to supply the direct current power boosted to the inverter 10. The boost converter 20 is arranged on the side of the base 50 opposite to the load 210. Accordingly, even in a case in which the power conversion apparatus 100 is arranged on or above the load 210, because the boost converter 20 is arranged on the side opposite to the load 210, it is possible to easily replace the boost converter 20.

In this embodiment, as described above, the boost converter 20 is fixed to the base 50 by the fasteners 80. According to this configuration, the boost converter 20 can be easily replaced simply by releasing fastened states of the fasteners 80.

### Modified Embodiments

Note that the embodiment disclosed this time must be considered as illustrative in all points and not restrictive. The scope of the other embodiments according to the present invention is not shown by the above description of the embodiments but by the scope of claims for patent, and all modifications (modified examples) within the meaning and scope equivalent to the scope of claims for patent are further included.

While the example in which the housing 70 has an opening on a side (Z1 side) opposite the load 210 has been shown in the aforementioned embodiment, the present invention is not limited to this. For example, alternatively, in one or more arrangements, the opening of the housing 70 on the side (Z1 side) opposite the load 210 is covered by a lid, or the like.

While the example in which the housing 70 is fixed to the load 210 by the fasteners 80 has been shown in the aforementioned embodiment, the present invention is not limited to this. For example, alternatively, in one or more arrangements, the housing 70 is fixed to the load 210 by fitting the housing 70 into the load 210.

While the example in which the power conversion apparatus 100 is arranged on the electric motor for the electric car has been shown in the aforementioned embodiment, the present invention is not limited to this. For example, alternatively, in one or more arrangements, the power conversion apparatus 100 is arranged on or above a load other than the electric motor for the electric car (e.g., an electric motor for an industrial machine).

While the example in which the inverter 10 and the DCDC converter 30 are arranged on the base 50 having the cooling flow path 51 has been shown in the aforementioned embodiment, the present invention is not limited to this. For example, alternatively, in one or more arrangement, the inverter 10 and the DCDC converter 30 are arranged on a plate member having no cooling flow path 51.

While the example in which the DCDC converter 30 and the boost converter 20 are fixed to the base 50 by fasteners 80 has been shown in the aforementioned embodiment, the present invention is not limited to this. For example, alternatively, in one or more arrangement, the DCDC converter 30 and the boost converter 20 are fixed to the base 50 by a thermally conductive adhesive.

While the example in which the boost converter 20 is arranged on the side (Z1 side) of the load 210 opposite to the base 50 has been shown in the aforementioned embodiment, the present invention is not limited to this. For example, alternatively, in one or more arrangement, the boost converter 20 is arranged on the load 210 side (Z2 side) of the base 50.

While the example in which two inverters, which are the first inverter 10a and the second inverter 10b, are provided, and two loads, which are the first load 210a and the second load 210b, are provided has been shown in the aforementioned embodiment, the present invention is not limited to this. For example, alternatively, in one or more arrangement, a single inverter and a single load are provided.

What is claimed is:

1. A power conversion apparatus configured to be arranged on or above a load for supplying electric power to the load, the power conversion apparatus comprising:
an inverter for converting direct current power input from a direct current power supply into alternate current power and supplying the alternate current power to the load; and
a direct current/direct current converter for converting a voltage of the direct current power into a different voltage, wherein
the inverter and the direct current/direct current converter are layered in this order from the load side.

2. The power conversion apparatus according to claim 1, further comprising a housing accommodating the inverter and the direct current/direct current converter, wherein
the housing has an opening on a side opposite the load; and
the direct current/direct current converter is exposed through the opening of the housing.

3. The power conversion apparatus according to claim 2, wherein the housing is fixed to the load by a fastener.

4. The power conversion apparatus according to claim 1, wherein the load includes an electric motor for an electric car.

5. The power conversion apparatus according to claim 1, further comprising a base on or above which the inverter and the direct current/direct current converter are arranged, wherein
the direct current/direct current converter is arranged on a side of the base opposite to the load.

6. The power conversion apparatus according to claim 5, wherein the direct current/direct current converter is fixed to the base by a fastener.

7. The power conversion apparatus according to claim 1, further comprising:
a base on or above which the inverter and the direct current/direct current converter are arranged; and
a boost converter arranged on an input side of the inverter to boost the direct current power input from the direct current power supply and to supply the direct current power boosted to the inverter; and
the boost converter is arranged on a side of the base opposite to the load.

8. The power conversion apparatus according to claim 7, wherein the boost converter is fixed to the base by a fastener.
